(19) United States
(12) Patent Application Publication
(10) Pub. No.: US 2025/0273933 A1
(43) Pub. Date: Aug. 28, 2025

(54) POWER CABINET

(71) Applicant: SUNGROW POWER SUPPLY CO., LTD., Hefei (CN)

(72) Inventors: Meng ZHOU, Hefei (CN); Kepeng JI, Hefei (CN)

(21) Appl. No.: 19/063,238

(22) Filed: Feb. 25, 2025

(30) Foreign Application Priority Data
Feb. 26, 2024 (CN) 202420356505.0

(51) Int. Cl. H02B 1/32

(52) U.S. Cl. CPC H02B 1/32

(57) ABSTRACT

Provided is a power cabinet including a first module provided with a first assembly portion and a second module provided with a second assembly portion. The first module has a first positioning groove formed on a bottom surface of the first module. The second module has a second positioning protrusion provided on a top surface thereof and a second positioning groove formed on a bottom surface thereof; or the first module has a first positioning groove formed on the bottom surface thereof, and the second module has a second positioning groove formed on the top surface thereof and a second positioning protrusion provided on the bottom surface thereof; or the first module is provided with a first positioning protrusion on a top surface thereof, and the second module has a second positioning protrusion provided on the top surface thereof and a second positioning groove formed on the bottom surface thereof.

### CROSS-REFERENCE TO RELATED APPLICATION

This application claims priority to Chinese Patent Application No. 202420356505.0 filed on Feb. 26, 2024, the entire disclosure of which is incorporated herein by reference.

### FIELD

The present disclosure belongs to the technical field of power cabinets, and in particular, to a power cabinet.

### BACKGROUND

Small household power cabinets are arranged in a module stacking manner. During the stacking, due to an electrical connection between modules through a hot-plug, the modules are affected by an external force to generate relative displacement, resulting in arcing or dumping. Therefore, the modules need to be position-limited or fixed. In most existing fixing methods, fixing is necessary for each mounting of the modules, which results in problems such as complex fixing structures of the modules and cumbersome system mounting.

### SUMMARY

The present disclosure aims to at least solve one of the technical problems existing in the related art. Therefore, embodiments of the present disclosure provide a power cabinet, which can simplify assembly steps, lower assembly difficulty, reduce use of parts and components, and exert positive effects on assembly, material consumption, processing efficiency, and the like.

In a first aspect, embodiments of the present disclosure provide a power cabinet. The power cabinet includes at least one first module provided with a first assembly portion, at least one second module provided with a second assembly portion, and an assembly member having an end connected to the first assembly portion or the second assembly portion and another end configured to be connected to one of the first assembly portion, the second assembly portion, or a support structure in a site where the power cabinet is located. The at least one first module and the at least one second module are stacked in a vertical direction. Each of the at least one first module has a first positioning groove formed on a bottom surface of the first module, and each of the at least one second module has a second positioning protrusion provided on a top surface of the second module and a second positioning groove formed on a bottom surface of the second module, in which one of the at least one first module is an uppermost module of multi-layer modules of the power cabinet; or each of the at least one first module has a first positioning groove formed on a bottom surface of the first module, and each of the at least one second module has a second positioning groove formed on a top surface of the second module and a second positioning protrusion provided on a bottom surface of the second module, in which one of the at least one first module is a lowermost module of multi-layer modules of the power cabinet; or each of the at least one first module has a first positioning protrusion provided on a top surface of the first module, and each of the at least one second module has a second positioning protrusion provided on a top surface of the second module and a second positioning groove formed on a bottom surface of the second module, in which one of the at least one second module is an uppermost module of multi-layer modules of the power cabinet, and one of the at least one first module is a lowermost module of the multi-layer modules of the power cabinet.

With the power cabinet according to the present disclosure, through the arrangement of the positioning groove, the second positioning protrusion, and the assembly member, position-limitation and fixing of the at least one first module and the at least one second module when vertically stacked are realized, which prevents the first module and the second module from arcing or dumping due to a relative displacement between the first module and the second module when being affected by an external force. Compared with a traditional method in which one fixing is required for each mounting of the modules, the assembly steps are simplified and the assembly difficulty is lowered while shortening mounting man-hours. Moreover, parts and components are reduced. In this way, positive effects are exerted on assembly, material consumption, processing efficiency, and the like.

According to an embodiment of the present disclosure, the first assembly portion is mounted at the top surface of the first module; and the second assembly portion is mounted at the top surface of the second module.

According to an embodiment of the present disclosure, each of the first assembly portion and the second assembly portion has a rear end extending to a back surface of the power cabinet.

According to an embodiment of the present disclosure, a projection of the first assembly portion on a horizontal plane is coincident with a projection of the second assembly portion on the horizontal plane.

According to an embodiment of the present disclosure, each of the first assembly portion and the second assembly portion is a recess. The recess is opened outwards at one of side walls of the recess.

According to an embodiment of the present disclosure, each of the at least one first module has a plurality of first positioning grooves, and each of the at least one second module has a plurality of second positioning grooves and a plurality of second positioning protrusions, in which the plurality of first positioning grooves, the plurality of second positioning grooves, and the plurality of second positioning protrusions are in one-to-one correspondence, and the plurality of second positioning protrusions is arranged at intervals on the top surface of each of the at least one second module; or each of the at least one first module has a plurality of first positioning grooves, and each of the at least one second module has a plurality of second positioning grooves and a plurality of second positioning protrusions, in which the plurality of first positioning grooves, the plurality of second positioning grooves, and the plurality of second positioning protrusions are in one-to-one correspondence, and the plurality of second positioning protrusions is arranged at intervals on the bottom surface of each of the at least one second module; or each of the at least one first module has a plurality of first positioning protrusions, and each of the at least one second module includes a plurality of second positioning grooves and a plurality of second positioning protrusions, in which the plurality of first positioning protrusions, the plurality of second positioning grooves, and the plurality of second positioning protrusions are in one-to-one correspondence, and the plurality of second positioning protrusions is arranged at intervals on the top surface of each of the at least one second module.

According to an embodiment of the present disclosure, the plurality of protrusions is arranged at intervals on respective edges of the top surface of each of the at least one second module; and/or the plurality of second positioning protrusions is arranged at intervals on respective edges of the bottom surface of each of the at least one second module; and/or the plurality of first positioning protrusions is arranged at intervals on respective edges of the bottom surface of each of the at least one first module.

According to an embodiment of the present disclosure, two ends of the assembly member are connected to the first modules or the second modules, in which the assembly member includes a body segment and a bent segment connected to two ends of the body segment and bent. The bent segment is connected to the first assembly portion or the second assembly portion.

According to an embodiment of the present disclosure, one first module and a plurality of second modules are provided. The one first module and the plurality of second modules are stacked in the vertical direction. The one first module is located above an uppermost second module of the plurality of second modules.

According to an embodiment of the present disclosure, two first module and at least one second module are provided. The two first modules and the at least one second module are stacked in the vertical direction. An uppermost first module of the two first modules is located above an uppermost second module of the at least one second module, and the at least one second module is arranged between the two first modules.

Additional aspects and advantages of the present disclosure will be given in part in the following description, or become apparent in part from the following description, or can be learned from practicing of the present disclosure.

### BRIEF DESCRIPTION OF THE DRAWINGS

The above and/or additional aspects and advantages of the present disclosure will become more apparent and more understandable from the following description of embodiments taken in conjunction with the accompanying drawings, in which:

FIG. 1 is an exploded structural view of a power cabinet according to an embodiment of the present disclosure.

FIG. 2 is a schematic structural view of a power cabinet according to an embodiment of the present disclosure.

FIG. 3 is a first cross-sectional view of a power cabinet according to an embodiment of the present disclosure.

FIG. 4 is a second cross-sectional view of a power cabinet according to an embodiment of the present disclosure.

FIG. 5 is a schematic structural view of a first module according to an embodiment of the present disclosure.

FIG. 6 is a cross-sectional view of a first module according to an embodiment of the present disclosure.

FIG. 7 is a schematic structural view of a second module according to an embodiment of the present disclosure.

FIG. 8 is a cross-sectional view of a second module according to an embodiment of the present disclosure.

FIG. 9 is a third cross-sectional view of a power cabinet according to an embodiment of the present disclosure.

FIG. 10 is a first exploded view of a partial structure of a power cabinet according to an embodiment of the present disclosure.

FIG. 11 is a fourth cross-sectional view of a power cabinet according to an embodiment of the present disclosure.

FIG. 12 is a second exploded view of a partial structure of a power cabinet according to an embodiment of the present disclosure.

### REFERENCE NUMERALS

power cabinet 100;
first module 110, first assembly portion 111, first positioning groove 112, first positioning protrusion 113;
second module 120, second assembly portion 121, second positioning groove 122, second positioning protrusion 123;
assembly member 130, body segment 131, bent segment 132.

### DETAILED DESCRIPTION

Embodiments of the present disclosure will be described in detail below with reference to examples thereof as illustrated in the accompanying drawings, throughout which same or similar elements, or elements having same or similar functions, are denoted by same or similar reference numerals. The embodiments described below with reference to the drawings are illustrative only, and are intended to explain, rather than limiting, the present disclosure.

Embodiments of the present disclosure disclose a power cabinet 100. The power cabinet 100 may be a household power cabinet.

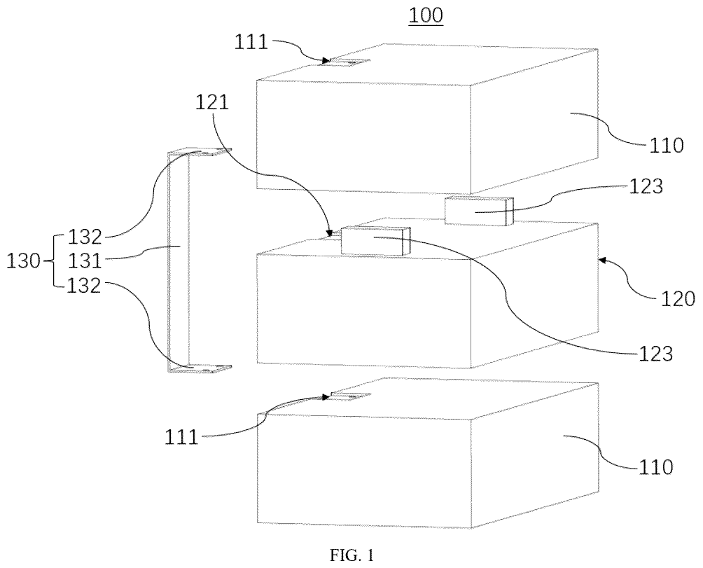

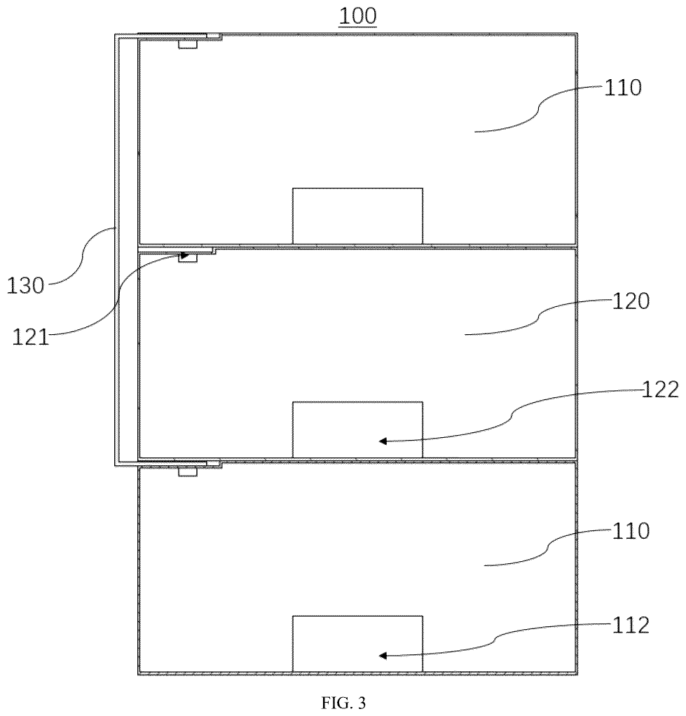

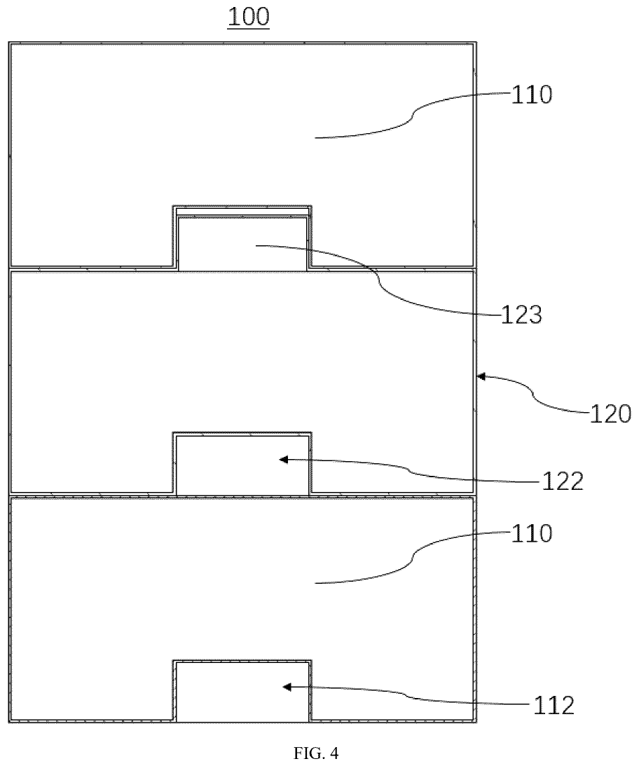

The power cabinet 100 according to the embodiments of the present disclosure will be described below with reference to FIG. 1 to FIG. 12.

In some embodiments, as shown in FIG. 1 to FIG. 3, the power cabinet 100 includes an assembly member 130, at least one first module 110, and at least one second module 120.

The first module 110 is provided with a first assembly portion 111. The second module 120 is provided with a second assembly portion 121. The at least one first module 110 and the at least one second module 120 are stacked and arranged in a vertical direction. The assembly member 130 has an end connected to the first assembly portion 111 or the second assembly portion 121 and another end configured to be connected to one of the first assembly portion 111, the second assembly portion 121, or a support structure in a site where the power cabinet 100 is located. Each of the at least one first module 110 has a first positioning groove 112 formed on a bottom surface of the first module 110, and each of the at least one second module 120 has a second positioning protrusion 123 provided on a top surface of the second module 120 and a second positioning groove 122 formed on a bottom surface of the second module 120, in which one of the at least one first module 110 is an uppermost module of multi-layer modules of the power cabinet 100. In an exemplary embodiment, each of the at least one first module 110 has a first positioning groove 112 formed on a bottom surface of the first module 110, and each of the at least one second module 120 has a second positioning groove 122 formed on a top surface of the second module 120 and a second positioning protrusion 123 provided on a bottom surface of the second module 120, in which one of the at least one first module 110 is a lowermost module of multi-layer modules of the power cabinet 100. In another exemplary embodiment, each of the at least one first module 110 has a first positioning protrusion 113 provided on a top surface of the first module 110, and each of the at least one second module 120 has a second positioning protrusion 123 provided on a top surface of the second module 120 and a second positioning groove 122 formed on a bottom surface of the second module 120, in which one of the at least one second module 120 is an uppermost module of multi-layer modules of the power cabinet 100, and one of the at least one first module 110 is a lowermost module of the multi-layer modules of the power cabinet 100.

The at least one first module 110 and the at least one second module 120 may be stacked. In other words, there may be one or more first modules 110 and one or more second modules 120.

For example, in some embodiments, as shown in FIG. 1 to FIG. 4, there may be two first modules 110 and one second module 120.

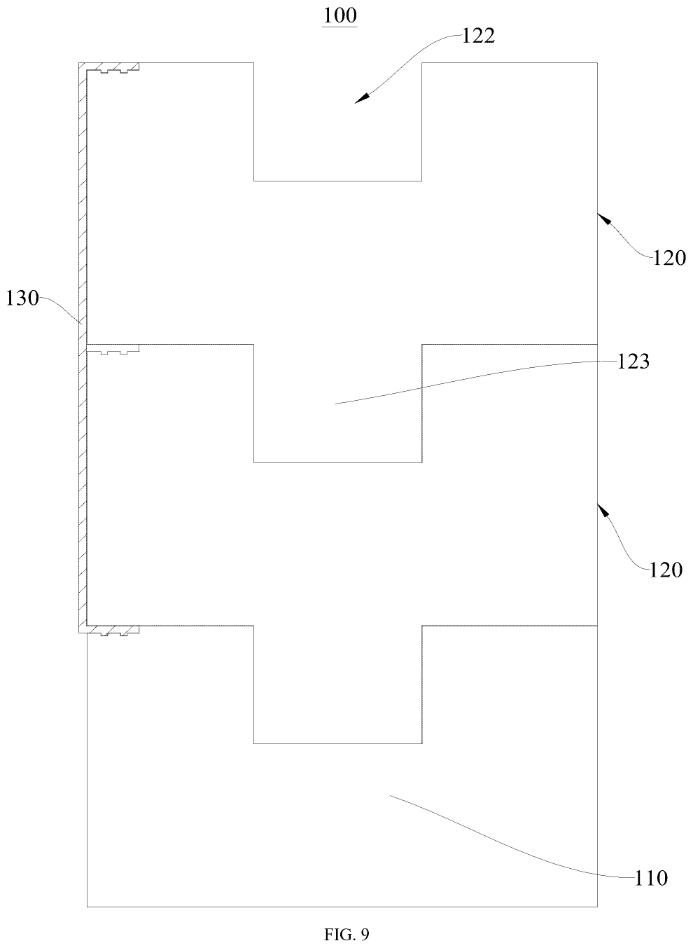

For example, in some other embodiments, as shown in FIG. 9 to FIG. 12, there may be one first module 110 and two second modules 120.

For example, in yet other embodiments, there may be one first module 110 and ten second modules 120.

The support structure in the site where the power cabinet 100 is located may be any fixed building structure or a stably and reliably inherent environment structure in the site where the power cabinet 100 is located, such as floor, wall, and post, which is not limited herein.

As shown in FIG. 1 to FIG. 4, the first module 110 is a structure recessed having a lower surface with a recess, and the second module 120 is a structure having an upper surface with a protrusion and a lower surface with a recess. The second positioning protrusion 123 of the second module 120 may be positioned and engaged into the first positioning groove 112 of the first module 110, or the second positioning protrusion 123 of the second module 120 may be positioned and engaged into a second positioning groove 122 of another second module 120 adjacent to the second module 120.

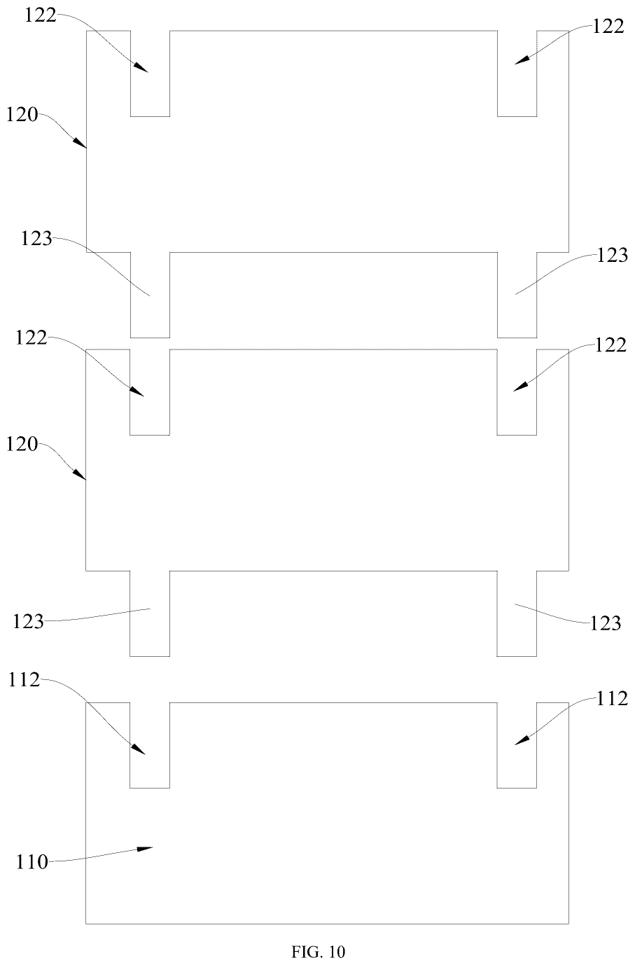

In an exemplary embodiment, as shown in FIG. 9 and FIG. 10, the first module 110 is a structure having an upper surface with a recess, and the second module 120 is a structure having an upper surface with a recess and a lower surface with a protrusion. The second positioning protrusion 123 of the second module 120 may be positioned and engaged into the first positioning groove 112 of the first module 110, or the second positioning protrusion 123 of the second module 120 may be positioned and engaged into the second positioning groove 122 of another second module 120 adjacent to the second module 120.

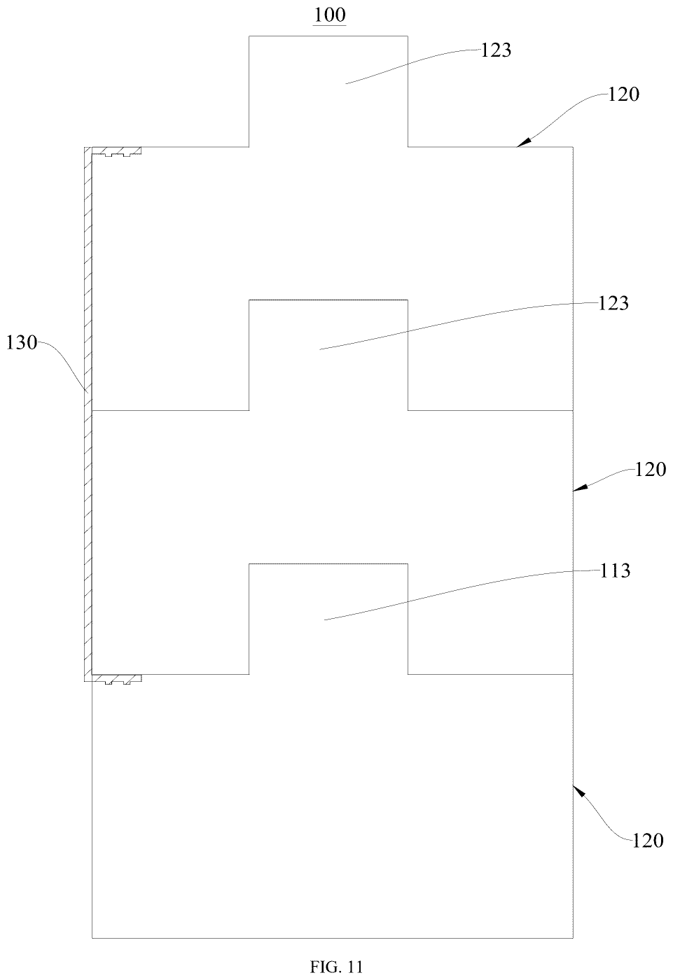

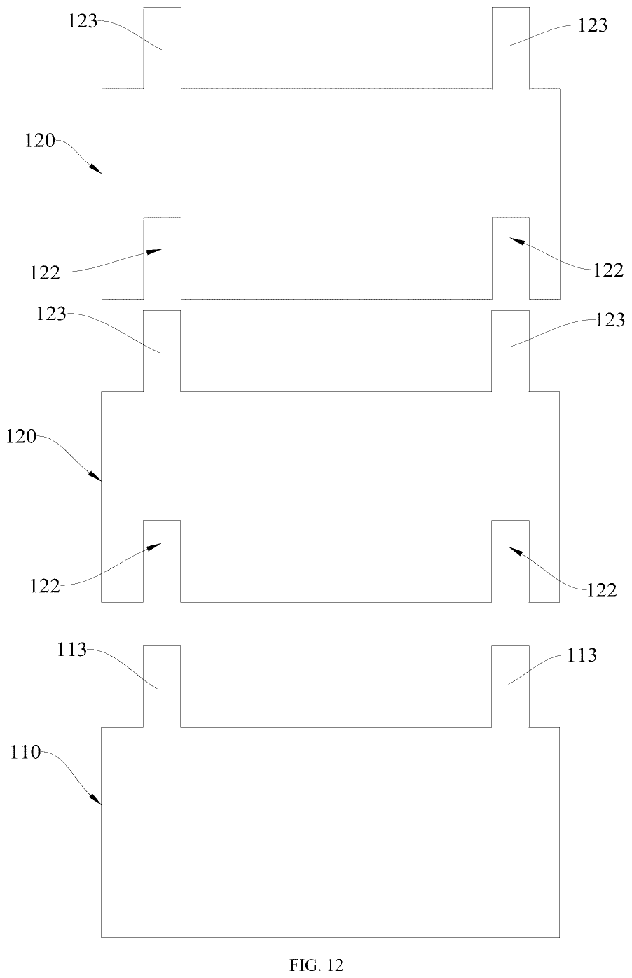

In another exemplary embodiment, as shown in FIG. 11 and FIG. 12, the first module 110 is a structure having an upper surface with a recess, and the second module 120 is a structure having an upper surface with a protrusion and a lower surface with a recess. The second positioning groove 122 of the second module 120 may be positioned and engaged with the first positioning protrusion 113 of the first module 110, or the second positioning groove 122 of the second module 120 may be positioned and engaged with the second positioning protrusion 123 of another second module 120 adjacent to the second module 120.

A connection between the assembly member 130 and the first assembly portion 111 may include, but is not limited to, a bolt connection, welding, an interference fit, and the like, which is not limited herein. For example, in some embodiments, as shown in FIG. 1 and

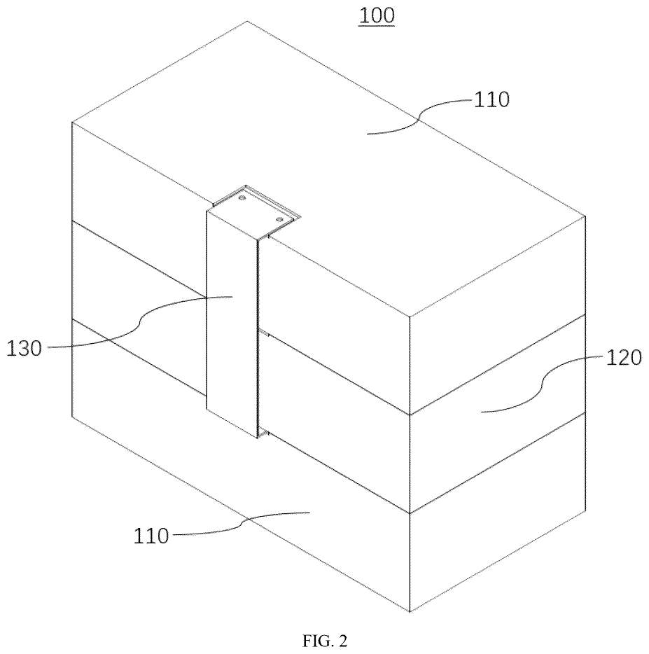

FIG. 2, the connection between the assembly member 130 and the first assembly portion 111 is implemented through the bolt connection.

A connection between the assembly member 130 and the second assembly portion 121 may include, but is not limited to, a bolt connection, welding, an interference fit, and the like, which is not limited herein. For example, in some embodiments, the connection between the assembly member 130 and the second assembly portion 121 is implemented through the bolt connection.

An assembly of the assembly member 130 may be implemented by at least one of the following five solutions.

For a first solution, as shown in FIG. 1 to FIG. 4, the assembly member 130 has an end connected to the first assembly portion 111 of the first module 110 and another end connected to a first assembly portion 111 of another first module 110.

For a second solution, as shown in FIG. 9 to FIG. 12, the assembly member 130 has an end connected to the first assembly portion 111 and another end connected to the second assembly portion 121.

For a third solution, the assembly member 130 has an end connected to the second assembly portion 121 of the second module 120 and another end connected to a second assembly portion 121 of another second module 120.

For a fourth solution, the assembly member 130 has an end connected to the first assembly portion 111 and another end connected to the support structure in the site where the power cabinet 100 is located.

For a fifth solution, the assembly member 130 has an end connected to the second assembly portion 121 and another end connected to the support structure in the site where the power cabinet 100 is located.

During actual implementation, in an example, as shown in FIG. 1 to FIG. 4, two first modules 110 and one second module 120 are stacked together, i.e., one first module 110, one second module 120, and one first module 110 are stacked sequentially in a top-to-bottom direction. One end of the assembly member 130 may be connected to the first assembly portion 111 of one of the two first modules 110, and the other end of the assembly member 130 may be connected to the first assembly portion 111 of the other first module 110. The second module 120 may be sandwiched between the two first modules 110. The second positioning protrusion 123 of the second module 120 may be positioned and engaged into the first positioning groove 112 of the uppermost first module 110 of the two first modules 110. In an exemplary embodiment, more modules may be provided by arranging a plurality of second modules 120 between the two first modules 110 or by arranging a plurality of second modules 120 below the lowermost first module 110 of the two first modules 110. A plurality of assembly members 130 may be arranged at intervals while providing more modules. In some embodiments, one assembly member 130 may be provided for every three modules.

In another example, as shown in FIG. 9 and FIG. 10, one first module 110 and two second modules 120 are stacked together, i.e., one second module 120, one second module 120, and one first module 110 are stacked sequentially in a top-to-bottom direction. One end of the assembly member 130 may be connected to the first assembly portion 111 of the first module 110, and the other end of the assembly member 130 may be connected to the second assembly portion 121 of one of the two second modules 120. The one first module 110 may be a lowest module of the power cabinet 100, and the second positioning protrusion 123 of the other one of the two second modules 120 may be positioned and engaged into the first positioning groove 112 of the lowermost first module 110. More modules may be provided by arranging a plurality of first modules 110 and/or a plurality of second modules 120 above the lowermost first module 110.

In a yet another example, as shown in FIG. 11 and FIG. 12, one first module 110 and two second modules 120 are stacked together, i.e., one second module 120, one second module 120, and one first module 110 are stacked sequentially in a top-to-bottom direction. One end of the assembly member 130 may be connected to the first assembly portion 111 of the first module 110, and the other end of the assembly member 130 may be connected to the second assembly portion 121 of one of the two second modules 120. The one of the two second modules 120 may be an uppermost module of the power cabinet 100, and the first module 110 may be a lowermost module of the power cabinet 100. The second positioning protrusion 123 of the uppermost second module 120 may be positioned and engaged into the second positioning groove 122 of a further second module 120. The first positioning protrusion 113 of the lowermost first module 110 may be positioned and engaged into the second positioning groove 122 of the other one of the two second modules 120. More modules may be provided by arranging a plurality of second modules 120 above the lowermost first module 110.

In the power cabinet 100 according to the embodiments of the present disclosure, through the arrangement of the positioning groove, the second positioning protrusion 123, and the assembly member 130, position-limitation and fixing of the at least one first module 110 and the at least one second module 120 when being vertically stacked are realized, which can prevent the first module 110 and the second module 120 from arcing or dumping due to the relative displacement between the first module 110 and the second module 120 when being affected by an external force. Compared with the traditional method in which one fixing is required for each mounting of the modules, the assembly steps are simplified and the assembly difficulty is lowered while shortening mounting man-hours. Moreover, parts and components are reduced. In this way, positive effects are exerted on assembly, material consumption, processing efficiency, and the like.

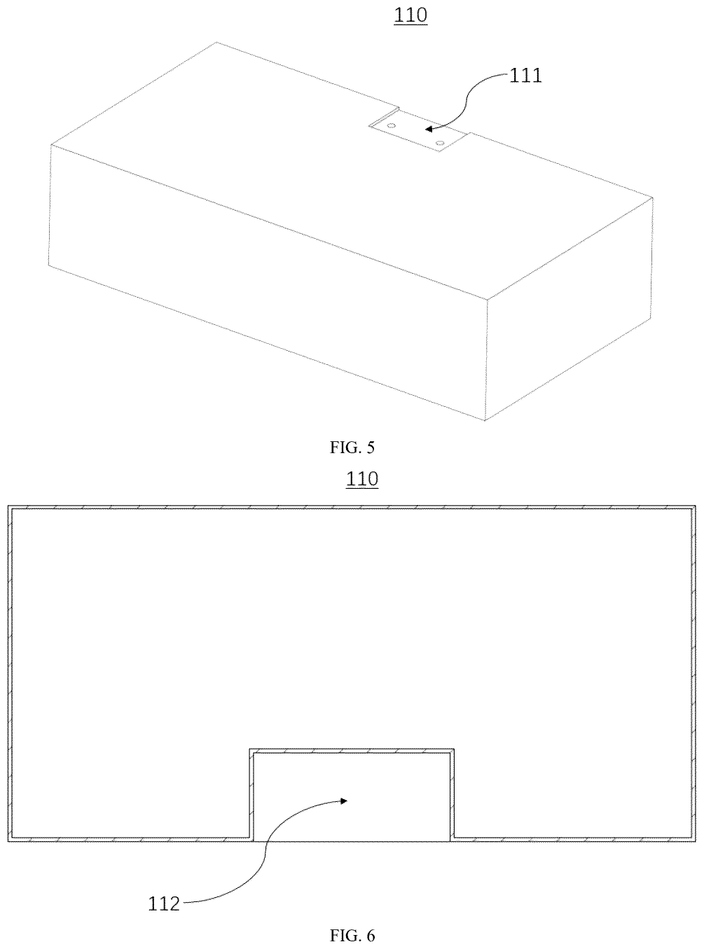

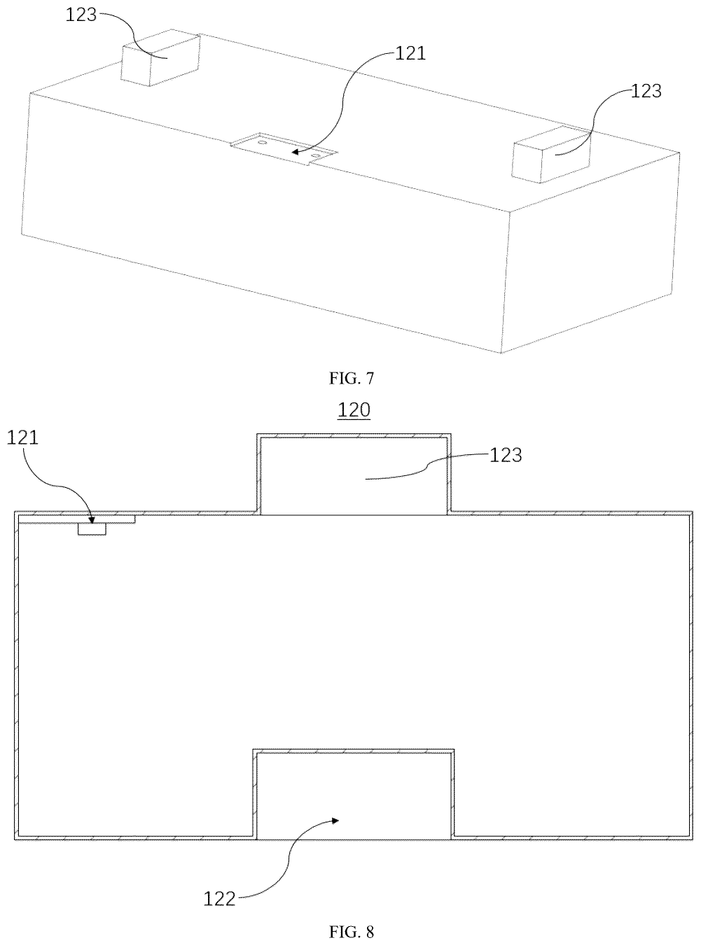

In some embodiments, as shown in FIG. 1 to FIG. 3, FIG. 5, FIG. 7 to FIG. 9, and FIG. 11, the first assembly portion 111 may be mounted on the top surface of the first module 110, and the second assembly portion 121 may be mounted on the top surface of the second module 120.

In this implementation, as shown in FIG. 1 to FIG. 3, FIG. 5, FIG. 7 to FIG. 9, and FIG. 11, the first assembly portion 111 may be located at an edge of the top surface of the first module 110, and may be located at a middle of the edge. The second assembly portion 121 may be located at an edge of the top surface of the second module 120, and may be located at a middle of the edge.

In another implementation, the first assembly portion 111 may be mounted on the bottom surface of the first module 110, and the second assembly portion 121 may be mounted on the bottom surface of the second module 120.

In a yet another implementation, the first assembly portion 111 may be mounted on a side surface of the first module 110, and the second assembly portion 121 may be mounted on a side surface of the second module 120.

In the power cabinet 100 according to the embodiments of the present disclosure, assembly positions of the second module 120 and the second module 120 are concentrated on the top surface through the design of the arrangement position of the assembly portion as described above. Compared with the bottom surface and the side surface, a stress strength between the assembly member 130 and the first module 110 and a stress strength between the assembly member 130 and the second module 120 are enhanced. Meanwhile, the assembly member 130 is prevented from causing serious corrosion due to direct contact with ground dirt. Therefore, a service life of the entire power cabinet 100 can be prolonged.

In some embodiments, as shown in FIG. 1 to FIG. 3, FIG. 9, and FIG. 11, each of the first assembly portion 111 and the second assembly portion 121 has a rear end extending to a back surface of the power cabinet 100.

In this implementation, as shown in FIG. 1 to FIG. 3, FIG. 9, and FIG. 11, the assembly member 130 may be attached to the back surface of the power cabinet 100. A front surface of the power cabinet 100 may be user-oriented, and the back surface of the power cabinet 100 may face towards a wall. The assembly member 130 may be connected to the first assembly portion 111 and the second assembly portion 121 in a rear-to-front direction. The assembly member 130 may be hidden between the wall and the stacked modules after the power cabinet 100 is mounted on the ground.

In the power cabinet 100 according to the embodiments of the present disclosure, through the design of the arrangement of the assembly member 130, the assembly member 130 may be hidden between the wall and the stacked modules after the product is deployed, to prevent the assembly member 130 from being exposed, which would cause the assembly member 130 to be easily impacted by external objects during a service cycle. Therefore, a probability of damage or even failure of the assembly members 130 due to external disturbances can be lowered.

In some embodiments, as shown in FIG. 1 to FIG. 3, FIG. 9, and FIG. 11, a projection of the first assembly portion 111 on a horizontal plane is coincident with a projection of the second assembly portion 121 on the horizontal plane.

In this implementation, as shown in FIG. 1 to FIG. 3, one end of the assembly member 130 is connected to the first assembly portion 111 of one of the two first modules 110, and the other end of the assembly member 130 is connected to the first assembly portion 111 of the other first module 110. The second module 120 may be sandwiched between the two first modules 110. The second positioning protrusion 123 of the second module 120 may be positioned and engaged into the first positioning groove 112 of the uppermost first module 110. After the assembly member 130 is mounted, based on a structural design where the projection of the first assembly portion 111 on the horizontal plane is coincident with the projection of the second assembly portion 121 on the horizontal plane, the assembly member 130 may shield the second assembly portion 121 of the second module 120 located between the two first modules 110.

In another implementation, the projection of the first assembly portion 111 on the horizontal plane may be partially coincident with the projection of the second assembly portion 121 on the horizontal plane.

In yet another implementation, the projection of the first assembly portion 111 on the horizontal plane may be completely in-coincident with the projection of the second assembly portion 121 on the horizontal plane.

In the power cabinet 100 according to the embodiments of the present disclosure, through a spatial position design of the first assembly portion 111 and the second assembly portion 121 as described above, the first assembly portion 111 and the second assembly portion 121 are located at a same position in the horizontal direction, and the assembly member 130 in a vertical state may be connected to both the first assembly portion 111 and the second assembly portion 121, which saves a material cost of the assembly member 130 while facilitating processing.

In some embodiments, as shown in FIG. 1 to FIG. 3, FIG. 5, FIG. 7 to FIG. 9, and FIG. 11, each of the first assembly portion 111 and the second assembly portion 121 is a recess. The recess is opened outwards at one of side walls of the recess.

In this implementation, as shown in FIG. 1 to FIG. 3, FIG. 5, FIG. 7 to FIG. 9, and FIG. 11, a rear end of the recess may extend to the back surface of the power cabinet 100 and be opened. The recess may be provided with a threaded hole at a bottom wall of the recess. The assembly member 130 may be provided with a corresponding connection hole. When the assembly member 130 is engaged with the first assembly portion 111 or the second assembly portion 121, the assembly member 130 may be pushed forwards into the recess from the back surface of the power cabinet 100, and a threaded connector may pass through the connection hole and the threaded hole and then be tightened for fixing.

In another implementation, each of the first assembly portion 111 and the second assembly portion 121 may be a snap.

In a yet another implementation, each of the first assembly portion 111 and the second assembly portion 121 may be a protrusion.

In the power cabinet 100 according to the embodiments of the present disclosure, through the structural design where each of the first assembly portion 111 and the second assembly portion 121 is a recess, after the assembly member 130 is connected to the modules, the adjacent modules may be in a tightly attached state, to prevent an upper-layer module from upwarping, thereby improving structure reliability of the entire power cabinet 100.

In some embodiments, as shown in FIG. 1, FIG. 7, FIG. 10, and FIG. 12, each of the at least one first module 110 may have a plurality of first positioning grooves 112, and each of the at least one second module 120 may have a plurality of second positioning grooves 122 and a plurality of second positioning protrusions 123, in which the plurality of first positioning grooves 112, the plurality of second positioning grooves 122, and the plurality of second positioning protrusions 123 may be in one-to-one correspondence, and the plurality of second positioning protrusions 123 may be arranged at intervals on the top surface of each of the at least one second module 120; or each of the at least one first module 110 may have a plurality of first positioning grooves 112, and each of the at least one second module 120 may have a plurality of second positioning grooves 122 and a plurality of second positioning protrusions 123, in which the plurality of first positioning grooves 112, the plurality of second positioning grooves 122, and the plurality of second positioning protrusions 123 may be in one-to-one correspondence, and the plurality of second positioning protrusions 123 may be arranged at intervals on the bottom surface of each of the at least one second module 120; or each of the at least one first module 110 may have a plurality of first positioning protrusions 113, and each of the at least one second module 120 may have a plurality of second positioning grooves 122 and a plurality of second positioning protrusions 123, in which the plurality of first positioning protrusions 113, the plurality of second positioning grooves 122, and the plurality of second positioning protrusions 123 may be in one-to-one correspondence, and the plurality of second positioning protrusions 123 may be arranged at intervals on the top surface of each of the at least one second module 120.

For example, the term “plurality of” means two or more. For example, in some embodiments, as shown in FIG. 1 and FIG. 7, each first module 110 may include two first positioning grooves 112, and each second module 120 may include two second positioning grooves 122 and two second positioning protrusions 123. In this case, the two first positioning grooves 112, the two second positioning grooves 122, and the two second positioning protrusions 123 may be in one-to-one correspondence, and the two second positioning protrusions 123 may be spaced apart from each other on the top surface of each second module 120.

In this implementation, as shown in FIG. 1, FIG. 7, FIG. 10, and FIG. 12, the two second positioning protrusions may be opposite to each other.

In another implementation, the two second positioning protrusions may also be offset from each other.

In the power cabinet 100 according to the embodiments of the present disclosure, through the design where each second module 120 includes the plurality of second positioning grooves 122 and the plurality of second positioning protrusions 123 as described above, it is further realized that the positions of the at least one first module 110 and the at least one second module 120 are limited when the at least one first module 110 and the at least one second module 120 are stacked in the vertical direction, which can prevent the first module 110 and the second module 120 from arcing or dumping due to the relative displacement between the first module 110 and the second module 120 when being affected by the external force as much as possible. Meanwhile, positioning accuracy can be improved during the stacking.

In some embodiments, as shown in FIG. 1, FIG. 7, FIG. 10, and FIG. 12, the plurality of second positioning protrusions 123 may be arranged at intervals on respective edges of the top surface of the second module 120; and/or the plurality of second positioning protrusions 123 may be arranged at intervals on respective edges of the bottom surface of the second module 120; and/or the plurality of first positioning protrusions 113 may be arranged at intervals on respective edges of the bottom surface of the first module 110.

In this implementation, exemplarily, as shown in FIG. 1 and FIG. 7, the two second positioning protrusions 123 may be spaced apart from each other on the top surface of the second module 120, and may be located on two different edges of the top surface of the second module 120. Further, the two second positioning protrusions 123 may be arranged separately from the second assembly portion 121, and the two second positioning protrusions 123 and the second assembly portion 121 may be located on three different edges of the top surface of the second module 120.

In an example, as shown in FIG. 10, the two second positioning protrusions 123 may be spaced apart from each other on the bottom surface of each second module 120, and may be located on two different edges of the bottom surface of each second module 120.

In another example, as shown in FIG. 12, the two first positioning protrusions 113 are spaced apart from each other on the top surface of the first module 110, and may be located on two different edges of the top surface of the first module 110. Further, the two first positioning protrusions 113 may be arranged separately from the first assembly portion 111, and the two first positioning protrusions 113 and the first assembly portion 111 may be located on three different edges of the top surface of the second module 120. The second positioning protrusions 123 may be spaced apart from each other on the top surface of each second module 120, and may be located on two different edges of the top surface of each second module 120. Further, the second positioning protrusions 123 may be arranged separately from the second assembly portion 121, and the two second positioning protrusions 123 and the second assembly portion 121 may be located on three different edges of the top surface of each second module 120.

In another implementation, three protrusions may be arranged at intervals on three edges of the top surface of the second module 120.

In a yet another implementation, four protrusions may be arranged at intervals on four edges of the top surface of the second module 120.

In the power cabinet 100 according to the embodiments of the present disclosure, through a structural design where the plurality of protrusions are arranged at intervals on the respective edge of the top surface of the second module 120, it is realized that position-limit and mounting of different edges of the top surface of each second module 120 are performed by the plurality of protrusions. Therefore, an offset between different modules when the stacking the modules can be reduced while improving a structural strength of the entire power cabinet 100.

In some embodiments, as shown in FIG. 1 to FIG. 3, FIG. 9, and FIG. 11, in a case where two ends of the assembly member 130 are connected to the first modules 110 or the second modules 120, the assembly member 130 may include a body segment 131 and a bent segment 132 connected to two ends of the body segment 131 and bent. The bent segment 132 may be connected to the first assembly portion 111 or the second assembly portion 121.

The assembly member 130 may be a sheet metal part. In an example, the assembly member 130 may be made of a material including, but not limited to, aluminum alloy, stainless steel, titanium alloy, or the like, which is not limited herein. For example, in some embodiments, the assembly member 130 may be made of stainless steel.

In this implementation, as shown in FIG. 1 to FIG. 3, FIG. 9, and FIG. 11, two bent segments 132 connected to two ends of the body segment 131 may have the same bending directions. The body segment 131 may be attached to the back surface of the power cabinet 100. Each of the first assembly portion 111 and the second assembly portion 121 may be a recess. When the assembly member 130 is engaged with the first assembly portion 111 or the second assembly portion 121, the bent segment 132 may be mounted in the recess, and the threaded connector may pass through the connection hole on the bent segment 132 and the threaded hole on the bottom wall of the recess and then be tightened for fixing.

In the power cabinet 100 according to the embodiments of the present disclosure, a connection between two modules or a connection between a single module and the support structure in the site where the power cabinet 100 is located is realized through the arrangement of the body segment 131 and the bent segment 132 as described above. As a result, an overall structure is simple and functional partition is clear. Therefore, a miniaturization and lightweight design is realized, which is conducive to mass production.

In some embodiments, the at least one first module 110 includes one first module 110. The at least one second module 120 may include a plurality of second modules 120. The one first module 110 and the plurality of second modules 120 may be stacked in the vertical direction. The one first module 110 may be located above an uppermost second module 120 of the plurality of second modules 120.

In this implementation, two ends of the assembly member 130 may be respectively connected to one first module 110 and one second module 120. At least one second module 120 may be sandwiched between the one first module 110 and the one second module 120. Further, the one first module 110 severs as the uppermost module, and the second positioning protrusion 123 of the uppermost second module 120 of the at least one second module 120 may be positioned and engaged with the first positioning groove 112 of the uppermost first module 110. In this case, more second modules 120 may be provided by arranging a plurality of second modules 120 between the first module 110 and the second module 120 that are connected by the assembly member 130; or more second modules 120 may be provided by arranging a plurality of second modules 120 below the second module 120 to which the assembly member 130 is connected.

In the power cabinet 100 according to the embodiments of the present disclosure, through the design of the stacking manner of one first module 110 and the plurality of second modules 120 as described above, the assembly member 130 may be connected to the first module 110 and the second module 120 simultaneously, and the number of the modules may be adjusted in different manner as desired, thereby increasing flexibility and practicability of the power cabinet 100. Meanwhile, the overall structure is simplified, mounting and fixed connection parts of the modules are reduced, and mounting steps are reduced while ensuring a reliable connection.

In some embodiments, as shown in FIG. 1 to FIG. 4, two first modules 110 and at least one second module 120 may be provided. The two first modules 110 and the at least one second module 120 may be stacked in the vertical direction. In this case, an uppermost first module 110 of the two first modules 110 may be located above an uppermost second module 120 of the at least one second modules 120, and the at least one second module 120 may be provided between the two first modules 110.

The embodiments of the present disclosure will be described in detail below from two different implementations.

In a first implementation, two ends of the assembly member 130 are connected to two first modules 110, respectively.

In this implementation, as shown in FIG. 1 to FIG. 4, the one end of the assembly member 130 may be connected to the first assembly portion 111 of one of the two first modules 110, and the other end of the assembly member 130 may be connected to the first assembly portion 111 of the other first module 110. The at least one second module 120 may be sandwiched between the two first modules 110. The second positioning protrusion 123 of the uppermost second module 120 may be positioned and engaged into the first positioning groove 112 of the uppermost first module 110 of the two first modules 110. In this case, more second modules 120 may be provided by arranging a plurality of second modules 120 between the two first modules 110 or by arranging a plurality of second modules 120 below the lowermost first module 110 of the two first modules 110.

In a second implementation, two ends of the assembly member 130 are respectively connected to one first module 110 and one second module 120.

In this implementation, the one end of the assembly member 130 may be connected to the first assembly portion 111 of the first module 110, and the other end of the assembly member 130 may be connected to the second assembly portion 121 of the second module 120. Moreover, the first module 110 severs as the uppermost module, and one first module 110 may be sandwiched between the first module 110 and the second module 120. In this case, more second modules 120 may be provided by arranging a plurality of second modules 120 between the first module 110 and the second module 120 that are connected by the assembly member 130, or by arranging a plurality of second modules 120 below the second modules 120 to which the assembly member 130 is connected.

In the power cabinet 100 according to the embodiments of the present disclosure, through the design of the stacking manner of the one first module 110 and the plurality of second modules 120, it is possible to select different arrangement to arrange the assembly member 130 and adjust the number of the modules as desired. Therefore, flexibility and diversity of the assembly manner of the power cabinet 100 is maximized while shortening the mounting man-hours. In addition, the use of spare and parts and components are reduced. In this way, positive effects are exerted on assembly, material consumption, processing efficiency, and the like.

Terms such as “first” and “second” in the embodiments and claims of the present disclosure are used only to distinguish between similar objects, rather than to describe a particular order or sequence. It should be understood that the data as used can be interchanged where appropriate, to enable the embodiments of the present disclosure described herein to be implemented in an order other than that illustrated or described herein. Also, the objects distinguished by the terms such as “first” and “second” are usually objects of the same type. The quantity of objects is not limited. For example, a first object may be one first object or plurality of first objects. In addition, “and/or” throughout the specification and claims indicates at least one of the objects associated with “and/or”. The character “/” generally indicates that the associated objects before and after the character are in an “or” relationship.

In the description of the present disclosure, it needs to be understood that, orientation or position relationship indicated by terms such as “over”, “below”, “front”, “back”, “vertical”, “horizontal”, “top”, “bottom”, “in”, and “out” is based on the orientation or position relationship shown in the accompanying drawings, and is merely for the convenience of describing the present disclosure and simplifying the description, rather than indicating or implying that the associated device or element must have a specific orientation, or be constructed and operated in a specific orientation, and therefore cannot be understood as a limitation on the present disclosure.

In the description of the present disclosure, “the first feature” and “the second feature” may include at least one of the features.

In the description of the present disclosure, “plurality” means at least two.

In the description of the present disclosure, the first feature being “on” or “under” the second feature may include the scenarios that the first feature is in direct contact with the second feature, or the first and second features, instead of being in direct contact with each other, are in contact with each other through another feature therebetween.

In the description of the present disclosure, the first feature being “above” the second feature may indicate that the first feature is directly above or obliquely above the second feature, or simply indicate that the level of the first feature is higher than that of the second feature.

In the description of this specification, descriptions with reference to the terms “an embodiment”, “some embodiments”, “illustrative embodiments”, “examples”, “specific examples”, or “some examples”, etc. mean that specific features, structure, materials, or characteristics described in conjunction with the embodiment or example are included in at least one embodiment or example of the present disclosure. In this specification, the schematic representations of the above terms do not necessarily refer to the same implementation or example. Moreover, the described specific features, structures, materials or characteristics may be combined in any one or more embodiments or examples in a suitable manner.

Although the embodiments of the present disclosure have been shown and described above, it can be understood by those of ordinary skill in the art that various changes, modifications, replacements, and variations may be made to these embodiments without departing from the principles and ideas of the present disclosure. The scope of the present disclosure is defined by the claims as appended and their equivalents.

What is claimed is:

1. A power cabinet, comprising:
at least one first module provided with a first assembly portion;
at least one second module provided with a second assembly portion, the at least one first module and the at least one second module being stacked in a vertical direction; and
an assembly member having an end connected to the first assembly portion or the second assembly portion and another end configured to be connected to one of the first assembly portion, the second assembly portion, or a support structure in a site where the power cabinet is located, wherein:
each of the at least one first module has a first positioning groove formed on a bottom surface of the first module, and each of the at least one second module has a second positioning protrusion provided on a top surface of the second module and a second positioning groove formed on a bottom surface of the second module, one of the at least one first module being an uppermost module of multi-layer modules of the power cabinet; or
each of the at least one first module has a first positioning groove formed on a bottom surface of the first module, and each of the at least one second module has a second positioning groove formed on a top surface of the second module and a second positioning protrusion provided on a bottom surface of the second module, one of the at least one first module being a lowermost module of multi-layer modules of the power cabinet; or
each of the at least one first module has a first positioning protrusion provided on a top surface of the first module, and each of the at least one second module has a second positioning protrusion provided on a top surface of the second module and a second positioning groove formed on a bottom surface of the second module, one of the at least one second module being an uppermost module of multi-layer modules of the power cabinet, and one of the at least one first module being a lowermost module of the multi-layer modules of the power cabinet.

2. The power cabinet according to claim 1, wherein:
the first assembly portion is mounted at the top surface of the first module; and
the second assembly portion is mounted at the top surface of the second module.

3. The power cabinet according to claim 2, wherein each of the first assembly portion and the second assembly portion has a rear end extending to a back surface of the power cabinet.

4. The power cabinet according to claim 2, wherein a projection of the first assembly portion on a horizontal plane is coincident with a projection of the second assembly portion on the horizontal plane.

5. The power cabinet according to claim 1, wherein each of the first assembly portion and the second assembly portion is a recess, the recess being opened outwards at one of side walls of the recess.

6. The power cabinet according to claim 1, wherein:
each of the at least one first module has a plurality of first positioning grooves, and each of the at least one second module has a plurality of second positioning grooves and a plurality of second positioning protrusions, wherein the plurality of first positioning grooves, the plurality of second positioning grooves, and the plurality of second positioning protrusions are in one-to-one correspondence, and wherein the plurality of second positioning protrusions is arranged at intervals on the top surface of each of the at least one second module; or
each of the at least one first module has a plurality of first positioning grooves, and each of the at least one second module has a plurality of second positioning grooves and a plurality of second positioning protrusions, wherein the plurality of first positioning grooves, the plurality of second positioning grooves, and the plurality of second positioning protrusions are in one-to-one correspondence, and wherein the plurality of second positioning protrusions is arranged at intervals on the bottom surface of each of the at least one second module; or
each of the at least one first module has a plurality of first positioning protrusions, and each of the at least one second module has a plurality of second positioning grooves and a plurality of second positioning protrusions, wherein the plurality of first positioning protrusions, the plurality of second positioning grooves, and the plurality of second positioning protrusions are in one-to-one correspondence, and wherein the plurality of second positioning protrusions is arranged at intervals on the top surface of each of the at least one second module.

7. The power cabinet according to claim 2, wherein:
each of the at least one first module has a plurality of first positioning grooves, and each of the at least one second module has a plurality of second positioning grooves and a plurality of second positioning protrusions, wherein the plurality of first positioning grooves, the plurality of second positioning grooves, and the plurality of second positioning protrusions are in one-to-one correspondence, and wherein the plurality of second positioning protrusions is arranged at intervals on the top surface of each of the at least one second module; or
each of the at least one first module has a plurality of first positioning grooves, and each of the at least one second module has a plurality of second positioning grooves and a plurality of second positioning protrusions, wherein the plurality of first positioning grooves, the plurality of second positioning grooves, and the plurality of second positioning protrusions are in one-to-one correspondence, and wherein the plurality of second positioning protrusions is arranged at intervals on the bottom surface of each of the at least one second module; or
each of the at least one first module has a plurality of first positioning protrusions, and each of the at least one second module has a plurality of second positioning grooves and a plurality of second positioning protrusions, wherein the plurality of first positioning protrusions, the plurality of second positioning grooves, and the plurality of second positioning protrusions are in one-to-one correspondence, and wherein the plurality of second positioning protrusions is arranged at intervals on the top surface of each of the at least one second module.

8. The power cabinet according to claim 3, wherein:
each of the at least one first module has a plurality of first positioning grooves, and each of the at least one second module has a plurality of second positioning grooves and a plurality of second positioning protrusions, wherein the plurality of first positioning grooves, the plurality of second positioning grooves, and the plurality of second positioning protrusions are in one-to-one correspondence, and wherein the plurality of second positioning protrusions is arranged at intervals on the top surface of each of the at least one second module; or
each of the at least one first module has a plurality of first positioning grooves, and each of the at least one second module has a plurality of second positioning grooves and a plurality of second positioning protrusions, wherein the plurality of first positioning grooves, the plurality of second positioning grooves, and the plurality of second positioning protrusions are in one-to-one correspondence, and wherein the plurality of second positioning protrusions is arranged at intervals on the bottom surface of each of the at least one second module; or
each of the at least one first module has a plurality of first positioning protrusions, and each of the at least one second module has a plurality of second positioning grooves and a plurality of second positioning protrusions, wherein the plurality of first positioning protrusions, the plurality of second positioning grooves, and the plurality of second positioning protrusions are in one-to-one correspondence, and wherein the plurality of second positioning protrusions is arranged at intervals on the top surface of each of the at least one second module.

9. The power cabinet according to claim 4, wherein:
each of the at least one first module has a plurality of first positioning grooves, and each of the at least one second module has a plurality of second positioning grooves and a plurality of second positioning protrusions, wherein the plurality of first positioning grooves, the plurality of second positioning grooves, and the plurality of second positioning protrusions are in one-to-one correspondence, and wherein the plurality of second positioning protrusions is arranged at intervals on the top surface of each of the at least one second module; or
each of the at least one first module has a plurality of first positioning grooves, and each of the at least one second module has a plurality of second positioning grooves and a plurality of second positioning protrusions, wherein the plurality of first positioning grooves, the plurality of second positioning grooves, and the plurality of second positioning protrusions are in one-to-one correspondence, and wherein the plurality of second positioning protrusions is arranged at intervals on the bottom surface of each of the at least one second module; or
each of the at least one first module has a plurality of first positioning protrusions, and each of the at least one second module has a plurality of second positioning grooves and a plurality of second positioning protrusions, wherein the plurality of first positioning protrusions, the plurality of second positioning grooves, and the plurality of second positioning protrusions are in one-to-one correspondence, and wherein the plurality of second positioning protrusions is arranged at intervals on the top surface of each of the at least one second module.

10. The power cabinet according to claim 5, wherein:
each of the at least one first module has a plurality of first positioning grooves, and each of the at least one second module has a plurality of second positioning grooves and a plurality of second positioning protrusions, wherein the plurality of first positioning grooves, the plurality of second positioning grooves, and the plurality of second positioning protrusions are in one-to-one correspondence, and wherein the plurality of second positioning protrusions is arranged at intervals on the top surface of each of the at least one second module; or
each of the at least one first module has a plurality of first positioning grooves, and each of the at least one second module has a plurality of second positioning grooves and a plurality of second positioning protrusions, wherein the plurality of first positioning grooves, the plurality of second positioning grooves, and the plurality of second positioning protrusions are in one-to-one correspondence, and wherein the plurality of second positioning protrusions is arranged at intervals on the bottom surface of each of the at least one second module; or
each of the at least one first module has a plurality of first positioning protrusions, and each of the at least one second module has a plurality of second positioning grooves and a plurality of second positioning protrusions, wherein the plurality of first positioning protrusions, the plurality of second positioning grooves, and the plurality of second positioning protrusions are in one-to-one correspondence, and wherein the plurality of second positioning protrusions is arranged at intervals on the top surface of each of the at least one second module.

11. The power cabinet according to claim 6, wherein:
the plurality of second positioning protrusions is arranged at intervals on respective edges of the top surface of each of the at least one second module; and/or
the plurality of second positioning protrusions is arranged at intervals on respective edges of the bottom surface of each of the at least one second module; and/or
the plurality of first positioning protrusions is arranged at intervals on respective edges of the bottom surface of each of the at least one first module.

12. The power cabinet according to claim 1, wherein two ends of the assembly member are connected to the first modules or the second modules, wherein the assembly member comprises a body segment and a bent segment connected to two ends of the body segment and bent, the bent segment being connected to the first assembly portion or the second assembly in portion.

13. The power cabinet according to claim 2, wherein two ends of the assembly member are connected to the first modules or the second modules, wherein the assembly member comprises a body segment and a bent segment connected to two ends of the body segment and bent, the bent segment being connected to the first assembly portion or the second assembly portion.

14. The power cabinet according to claim 3, wherein two ends of the assembly member are connected to the first modules or the second modules, wherein the assembly member comprises a body segment and a bent segment connected to two ends of the body segment and bent, the bent segment being connected to the first assembly portion or the second assembly portion.

15. The power cabinet according to claim 4, wherein two ends of the assembly member are connected to the first modules or the second modules, wherein the assembly member comprises a body segment and a bent segment connected to two ends of the body segment and bent, the bent segment being connected to the first assembly portion or the second assembly portion.

16. The power cabinet according to claim 5, wherein two ends of the assembly member are connected to the first modules or the second modules, wherein the assembly member comprises a body segment and a bent segment connected to two ends of the body segment and bent, the bent segment being connected to the first assembly portion or the second assembly portion.

17. The power cabinet according to claim 1, wherein one first module and a plurality of second modules are provided, the one first module and the plurality of second modules being stacked in the vertical direction,
wherein the one first module is located above an uppermost second module of the plurality of second modules.

18. The power cabinet according to claim 2, wherein one first module and a plurality of second modules are provided, the one first module and the plurality of second modules being stacked in the vertical direction,
wherein the one first module is located above an uppermost second module of the plurality of second modules.

19. The power cabinet according to claim 1, wherein two first modules and at least one second module are provided, the two first modules and the at least one second module being stacked in the vertical direction, wherein:
an uppermost first module of the two first modules is located above an uppermost second module of the at least one second module; and
the at least one second module is arranged between the two first modules.

20. The power cabinet according to claim 2, wherein two first modules and at least one second module are provided, the two first modules and the at least one second module being stacked in the vertical direction, wherein:
an uppermost first module of the two first modules is located above an uppermost second module of the at least one second module; and
the at least one second module is arranged between the two first modules.
